(19) United States
(12) Patent Application Publication
(10) Pub. No.: US 2008/0231142 A1
(43) Pub. Date: Sep. 25, 2008

(54) Piezoelectric Actuating Unit or Piezoelectric Drive Device

(76) Inventors: Bernhard Gottlieb, Munchen (DE); Andreas Kappel, Brunnthal (DE); Tim Schwebel, Munchen (DE); Carsten Wallenhauer, Schwarzheide (DE)

Correspondence Address: BAKER BOTTS L.L.P.;PATENT DEPARTMENT, 98 SAN JACINTO BLVD., SUITE 1500, AUSTIN, TX, 78701-4039, US

(21) Appl. No.: 12/066,566

(22) PCT Filed: Sep. 5, 2006
(86) PCT No.: PCT/EP2006/065993

§ 371 Date: Mar. 27, 2008

(30) Foreign Application Priority Data
Sep. 13, 2005 (DE) 10 2005 043 622.6

(51) Int. Cl. H01L 41/053; H01L 41/09

(52) U.S. Cl. 310/314

(57) ABSTRACT

A piezoelectric actuating unit has a piezoelectric actuator pressed to a first cap which makes it possible to fix the actuating unit thereabove to the drive body of the piezoelectric drive device and cables and/or contact pins used in the form of contact elements with the actuator for the electrical operation thereof. In an advantageous manner, the first cap has at least one orifice for introducing the contact element. In particularly advantageous manner, the actuating units are used in the piezoelectric drive device with a drive body which has a cylindrical drive surface, at least two actuating units provided with the piezoelectric actuators which displace the drive body on a drive plane, a drive shaft which is placed on the drive body surface and is rotated by oscillation and the contact elements for connecting an actuator operating circuit to the actuators.

### CROSS-REFERENCE TO RELATED APPLICATIONS

This application is a U.S. national stage application of International Application No. PCT/EP2006/065993 filed Sep. 5, 2006, which designates the United States of America, and claims priority to German application number 10 2005 043 622.6 filed Sep. 13, 2005, the contents of which are hereby incorporated by reference in their entirety.

### TECHNICAL FIELD

The invention relates to a piezoelectric actuating unit or to a piezoelectric drive device with such actuating units.

### BACKGROUND

Piezoelectric actuators are used in a wide variety of ways as actuating devices. They are used as drivers in a piezo motor, as is described in EP 1 098 429 B1. The outstanding feature of such a piezo motor is the provision of a high torque of for example 1 Nm to 5 Nm at a relatively low speed of less than 100 RPM and it is therefore primarily suited for actuation tasks requiring high torque but low rotational speed.

As is shown in FIG. 6, this type of piezo motor as a piezoactuator drive device has a drive body 1 with a cylindrical drive surface 2, at least two piezoelectric actuating units 3, which cause the drive body 1 to oscillate in a drive plane x, y, a drive shaft 4, which is in contact with the drive surface 2 running perpendicular to the drive plane and is caused to rotate by the oscillation, and an assigned switching device to drive the actuating units 3.

Central parts of this motor concept are piezoactuators which are surrounded by pre-stressed tubular springs. The tubular springs themselves are delimited at the top and at the bottom by two piezo caps, between which the piezoactuator sits. Such a structure with lower cap-tubular spring-piezoceramic-upper cap forms a self-contained actuating unit.

The actuating units are coupled to the drive body 1 in the piezo ring motor on their upper side via the upper cap through crimped, welded or screw connections to give mechanical rigidity against tensile, compressive, shear or bending stress. In the lower side of the actuating unit cable conduits are also embodied in the bottom cap to allow the passage of cables 5.

The actuating units 3 are connected to the switching device by means of the cables 5 which protrude from openings 6 in the housing 7, 8. The cables 5 for controlling the actuating unit 3 are routed out of the actuating units 3 at the rear, i.e. on the end of the actuating unit 3 facing away from the drive body 1. Accordingly the openings 6 are embodied in arm ends of the housing 7, 8. Such an arrangement is however not optimum as regards size and uniform cable routing. Any plug construction at the end of the arms would lead to significantly larger dimensions which would be a hindrance in a normal application.

### SUMMARY

The construction of a piezoelectric actuating unit or piezoelectric drive device with such an actuating unit can be improved according to an embodiment of a piezoelectric actuating unit for a piezoelectric drive device comprising a piezoelectric actuator tensioned against a first cap, with the first cap being embodied for attachment of the actuating unit via the first cap to a drive body of the piezoelectric drive device, and cables and/or contacting pins as contacting elements connected to the actuator for electrical control of the actuator, wherein the first cap comprises at least one opening to allow the passage of the contacting elements.

According to a further embodiment, the actuator may be tensioned by means of a spring element between the first cap and a second cap, with the actuator being arranged to expand and/or contract on excitation essentially in the direction of the two caps. According to a further embodiment, the spring element can be embodied as a tubular spring and may be arranged to surround the actuator. According to a further embodiment, According to a further embodiment, the first cap and the or a second cap may be connected positively to the spring element, with the second cap giving full-surface support to the actuator. According to a further embodiment, the first cap may be embodied for a mechanical coupling to elements of a drive body through a crimp, weld or screw connections. According to a further embodiment, the at least one opening may extend in a front-facing expansion or contraction direction of the actuator through the first cap. According to a further embodiment, the at least one opening may extend in a front-facing expansion or contraction direction of the actuator through the first cap and is embodied in the front-facing area of the at least one opening open to one side. According to a further embodiment, the at least one opening may extend sideways in relation to a front-facing expansion or contraction direction of the actuator through the first cap.

According to another embodiment, a piezoelectric drive device may comprise a drive body with a cylindrical drive surface, at least two actuating units with piezoelectric actuators as described above, which cause the drive body to start to oscillate in a drive plane, a drive shaft, which is in contact with the drive body surface and is caused to start rotating by the oscillation, and contacting elements for connecting to the actuators a circuit for driving the actuators.

According to a further embodiment, the piezoelectric drive may further comprising a housing and one or more plugs, which are embodied on the housing in a direction parallel to the axis of the shaft for connection of the contacting elements arranged within the housing from outside the housing to the circuit.

### BRIEF DESCRIPTION OF THE DRAWINGS

An exemplary embodiment is explained below in more detail on the basis of the drawing. The figures show:

FIG. 1 a piezoactuator drive device with actuating units with the upper housing removed, in a perspective view from above,

FIG. 2 a piezoactuator drive device in accordance with FIG. 1 with a closed housing,

FIG. 3 such an actuating unit in a sectional view,

FIG. 4 an upper cap of such an actuating unit with openings for bringing out cables at the front,

FIG. 5 the upper cap of such an actuating unit viewed from above and

FIG. 6 a piezoactuator drive device in accordance with the prior art with the housing closed, in a perspective view from above.

### DETAILED DESCRIPTION

Preferably a piezoelectric actuating unit for a piezoelectric drive device may accordingly be provided with a piezoelectric actuator tensioned against an upper cap, with the first cap being embodied for attaching the actuating unit via the first cap to a drive body of the piezoelectric drive device and with cables and/or contacting pins as contacting elements connected to the actuator for electrical control of the actuator, with the first cap having at least one opening to allow the passage of the contacting elements.

An actuating unit may be advantageous in which the actuator is tensioned by means of a spring element between the first cap and a second cap, with the actuator being arranged to expand and/or to contract on excitation essentially in the direction of the two caps. An actuating unit may be advantageous in which the spring element is embodied as a tubular spring and is arranged surrounding the actuator. An actuating unit may be advantageous in which a first cap and a second, lower cap are connected in a positive fit with the spring element, with the second cap providing the actuator with full-surface support. An actuating unit may be advantageous in which the first cap is embodied for a mechanical coupling to elements of a drive body through crimp, weld or screw connections.

An actuating unit may be advantageous in which the at least one opening extends in a front expansion or contraction direction of the actuator through the first cap. An actuating unit may be advantageous in which the at least one opening extends in a front-side expansion or contraction direction of the actuator through the first cap and in the front-side area of the at least one opening is embodied open to the side. An actuating unit may be advantageous in which the at least one opening extends sideways in relation to a front-side expansion or contraction direction of the actuator through the first cap.

A piezoelectric drive device with a drive body with a cylindrical drive surface may be preferred with at least two actuating units embodied with piezoelectric actuators causing the drive body to start to oscillate in a drive plane, a drive shaft, which is in contact with the drive body surface and is made to start to rotate by the oscillation, and contacting elements for connecting to the actuators a circuit to drive the actuators. Such a piezoelectric drive device is preferred with a housing and with one or more plugs which are embodied on the housing in a direction in parallel to the axis of the shaft for connection of the contacting elements arranged within the housing to the circuit from outside the housing.

A more compact construction of a piezoelectric actuator drive device is made possible by means of such actuating units, especially as a piezo ring motor with internal cable routing. A standardized electrical connection through an improved and more secure bringing out of the electrical connections is also made possible in this case.

The lower caps of the actuating units are merely embodied as delimiting elements. The upper caps are equipped with a dual functionality, to provide both a coupling between actuating unit and drive body and also to provide cable glands for the piezoactuator cables.

With the aid of such a construction the cables can be brought out centrally at preferably one point or where necessary a number of points from the motor housing. Cabling at the ends of the arms is no longer necessary; the motor can be built significantly smaller. Advantageously industry-standard plug-in connectors are able to be used for connection which guarantee an enhanced operational safety, e.g. through strain relief and compatibility with standard parts.

Advantages are provided by comparison with conventional designs of a piezo ring motor especially by greater integration, greater operational safety, a standardized cable routing and the ability to employ strain relief.

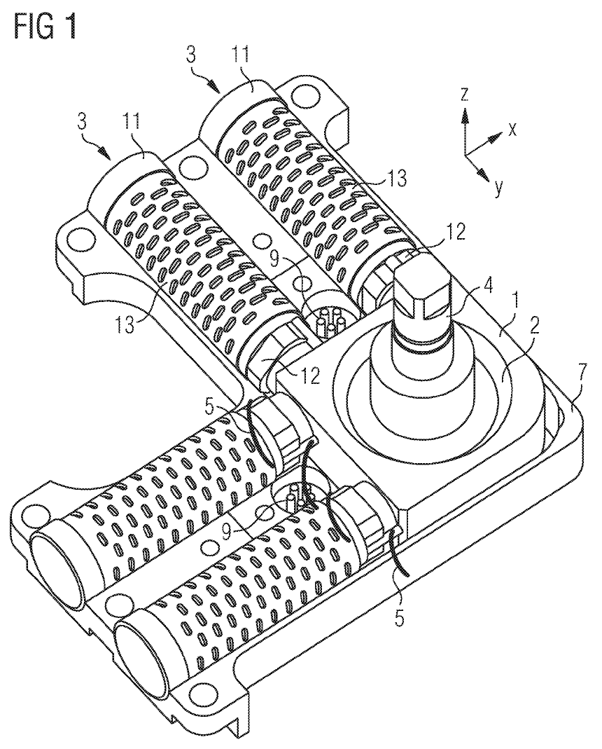

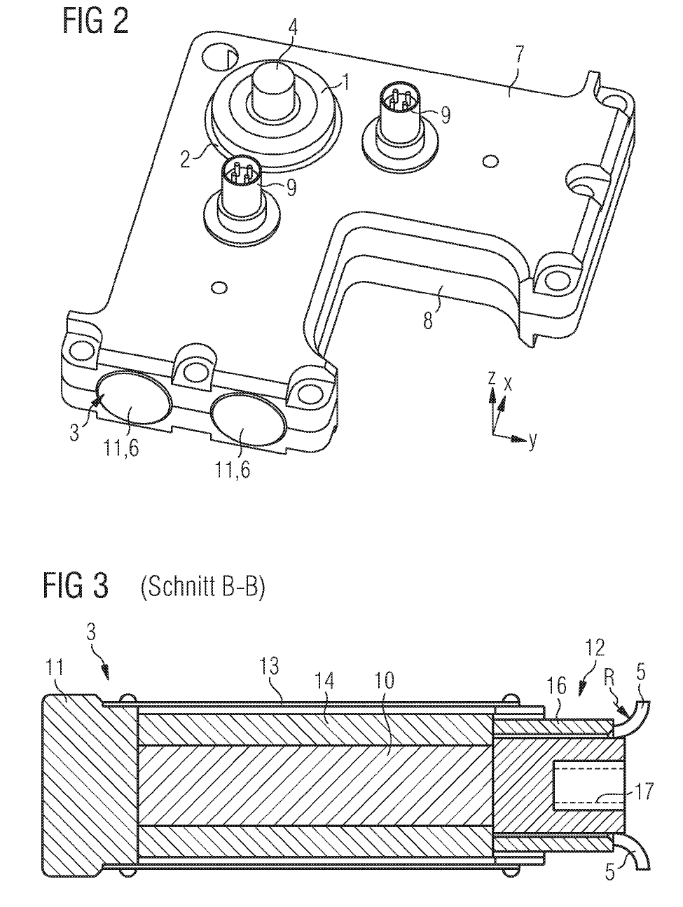

FIGS. 1 and 2 show a typical embodiment of a piezo actuator drive device in the form of a piezo ring motor with advantageously embodied actuating units 3.

The piezoactuator drive device comprises a plurality of components in a housing 7, 8 which are actively connected to one another. The central element is a drive body 1 with an internal or alternately external cylindrical drive surface 2. On the outer circumference of the drive body 1 illustrated are attached at least two, here especially four piezoelectric actuating units 3 which cause the drive body 1 to start oscillating in a drive plane x, y.

The actuating units 3 are coupled into the piezo ring motor on their front side or upper side via a first, upper cap 12 especially through crimp, weld or screw connections mechanically rigidly to the drive body 1 against tensile, compressive, shear or bending stresses. The rear ends of the actuating units 3 are attached to or supported on an inner wall of the housing 7, 8 to the sides of openings 6. Accordingly the openings 6 in the arm ends of the housing 7, 8, other than being used optionally for example to insert or replace the actuating units 3, are also dispensable.

A drive shaft 4, which is in contact with the drive surface 2 running at right angles to the drive plane in a third direction z is made to start rotating by the oscillation. The drive shaft 4 leads on at least one side out of the housing 7, 8 and is supported in or relative to a housing wall of the housing 7, 8. An internally or also externally-arranged switching device is used for driving the actuating units 3.

Further central parts of such a motor concept or also of an alternate drive concept with another type of construction are the actuating units 3. As can be seen especially from FIG. 3, the actuating units 3 are embodied with integrated piezoelectric actuators 10, which are preferably surrounded by a pre-tensioned tubular spring as a spring element 13. The tubular springs themselves are delimited at the top and at the bottom by two piezo caps, a base cap or second, lower cap 11 and an upper cap 12, between which the actual actuator 10 sits. Such a structure with lower cap 11-tubular spring-piezoceramic-upper cap 12 forms a self-contained actuating unit 3.

Preferably the lower cap 11 makes a positive connection with the spring element 13, advantageously through a weld. The base cap preferably provides the actuator 10 with extensive support. Preferably the upper cap 12 likewise has a positive connection to the spring element 13, advantageously through a weld. The upper cap 12 makes possible a mechanical coupling to further elements, e.g. the annular drive body 1 by crimp, weld or screwed connections. The upper cap simultaneously allows the passage of piezo actuator contacts or cables 5. The alignment of the elements is selected in such cases so that the actuator 10 expands or contracts on excitation essentially in the direction of the two caps 11, 12.

The actuating units 3 can be connected to the switching device by means of cables 5. The cables 5 for controlling the actuating units 3 are routed out of the actuating units on the front side, meaning at the end of the actuating units 3 facing the drive body 1.

A defined facility for connecting the cables 5 to the outside is established by the two connectors 9 each with a number of connector contacts shown in FIGS. 1 and 2. The routing of the cables 5 runs in such cases entirely within the motor or within its housing 7, 8. The lower caps 11 of the actuating units 3 merely serve to fix the units in the housing 7, 8. On the housing 7, 8 such connectors 9 are preferably embodied in a direction parallel to the axis of the shaft 4 for connecting the contacting elements 5 arranged within the housing 7, 8 from outside the housing 7, 8 to an external circuit.

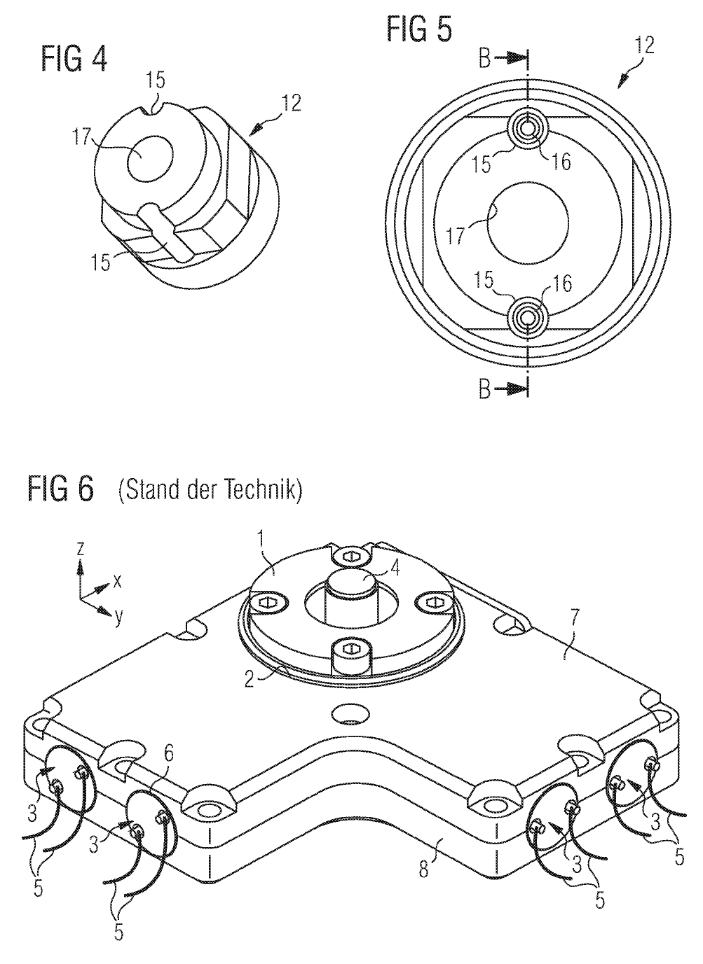

The upper cap 12, as can also be seen from FIGS. 4 and 5, has one or preferably two cable openings 15 in the form of for example holes forming channels which make it possible to route the two cables 5 out of the actuator 3. The cable openings 15 extend in a front-facing or axial direction. In order to enable the cables fed through these openings to be routed away sideways, the cable openings 15 are open to the sides in the front-facing area.

Introduced in each case into the cable openings 15 is a piezo contacting pin 16 as a contacting element for contacting the piezoactuator 10. The cable 5 is for example clamped between the corresponding contacting pin 16 and an adjacent wall of the upper cap 12 or is permanently attached to the contacting pin 16, e.g. soldered onto it.

Suitable selection of the length of the piezo contacting pins 16 allows a radius R of the cable routing (FIG. 3) to be influenced as a function of individual design conditions.

Where contacting of the actuator 10 with a contact has to be undertaken from the opposite lower side, one of the cable openings 15 is routed with a contacting pin fed through it if necessary, through a space to the side of the actuator, i.e. especially through the body of a silicon encapsulation 14 of the actuator 10.

The structure of the upper cap 12 is selected so that for example inside it, in one or more face-side threaded holes 17, threaded pins, e.g. with a standardized thread M4-M6, can be accommodated and a face-side annular support surface for optimum mechanical stiffness remains as large as possible. In addition or as an alternative there is the option of dispensing with threads and changing to alternate forms of coupling of the upper cap 12 to the drive body 1 by means of welding for example.

A plurality of alternate embodiments can be implemented. For example a coupling to further elements by means of a screw connection can be made possible via the threaded hole 17.

Instead of embodying the cable openings 15 open to the sides in the front-facing area, the cable openings can lead outwards from a stepped front-facing surface in an axial direction or at an angle to it in the direction of the actuator 10. The piezo contacting pins can especially also be routed out as litz wires or through an end section of the cable 5 as a contacting element. The piezo contacting pins can also be routed out directly in a sideways, especially radial instead of axial direction.

Advantageously the cable connection to the outside of the housing 7, 8 can be implemented by one plug but also by more than two plugs 9. Instead of a connection option via plug 9 the cables 5 can also be routed out through a suitable opening directly from the housing 7, 8.

What is claimed is:

1. A piezoelectric actuating unit for a piezoelectric drive device:
a piezoelectric actuator tensioned against a first cap, with the first cap being embodied for attachment of the actuating unit via the first cap to a drive body of the piezoelectric drive device, and
cables and/or contacting pins as contacting elements connected to the actuator for electrical control of the actuator,
wherein the first cap comprises at least one opening to allow the passage of the contacting elements.

2. The actuating unit according to claim 1, wherein the actuator is tensioned by means of a spring element between the first cap and a second cap, with the actuator being arranged to expand and/or contract on excitation essentially in the direction of the two caps.

3. The actuating unit according to claim 1, wherein the spring element is embodied as a tubular spring and is arranged to surround the actuator.

4. The actuating unit according to claim 1, wherein the first cap and the or a second cap is connected positively to the spring element, with the second cap giving full-surface support to the actuator.

5. The actuating unit according to claim 1, wherein the first cap is embodied for a mechanical coupling to elements of a drive body through a crimp, weld or screw connections.

6. The actuating unit according to claim 1, wherein the at least one opening extends in a front-facing expansion or contraction direction of the actuator through the first cap.

7. The actuating unit according to claim 6, wherein the at least one opening extends in a front-facing expansion or contraction direction of the actuator through the first cap and is embodied in the front-facing area of the at least one opening open to one side.

8. The actuating unit according to claim 1, wherein the at least one opening extends sideways in relation to a front-facing expansion or contraction direction of the actuator through the first cap.

9. A piezoelectric drive device comprising:
a drive body with a cylindrical drive surface,
at least two actuating units with piezoelectric actuators, which cause the drive body to start to oscillate in a drive plane,
a drive shaft, which is in contact with the drive body surface and is caused to start rotating by the oscillation, and
contacting elements for connecting to the actuators a circuit for driving the actuators,
wherein each actuating unit comprises:
a piezoelectric actuator tensioned against a first cap, with the first cap being embodied for attachment of the actuating unit via the first cap to a drive body of the piezoelectric drive device, and
cables and/or contacting pins as contacting elements connected to the actuator for electrical control of the actuator,
wherein the first cap comprises at least one opening to allow the passage of the contacting elements.

10. A piezoelectric drive device according to claim 9, further comprising a housing and one or more plugs, which are embodied on the housing in a direction parallel to the axis of the shaft for connection of the contacting elements arranged within the housing from outside the housing to the circuit.

11. The piezoelectric drive device according to claim 9, wherein the actuator is tensioned by means of a spring element between the first cap and a second cap, with the actuator being arranged to expand and/or contract on excitation essentially in the direction of the two caps.

12. The piezoelectric drive device according to claim 9, wherein the spring element is embodied as a tubular spring and is arranged to surround the actuator.

13. The piezoelectric drive device according to claim 9, wherein the first cap and the or a second cap is connected positively to the spring element, with the second cap giving full-surface support to the actuator.

14. The piezoelectric drive device according to claim 9, wherein the first cap is embodied for a mechanical coupling to elements of a drive body through a crimp, weld or screw connections.

15. The piezoelectric drive device according to claim 9, wherein the at least one opening extends in a front-facing expansion or contraction direction of the actuator through the first cap.

16. The piezoelectric drive device according to claim 15, wherein the at least one opening extends in a front-facing expansion or contraction direction of the actuator through the first cap and is embodied in the front-facing area of the at least one opening open to one side.

17. The piezoelectric drive device according to claim 9, wherein the at least one opening extends sideways in relation to a front-facing expansion or contraction direction of the actuator through the first cap.

18. A piezoelectric actuating unit for a piezoelectric drive device comprising:
a piezoelectric actuator tensioned against a first cap comprising at least one opening, with the first cap being embodied for attachment of the actuating unit via the first cap to a drive body of the piezoelectric drive device, and
cables and/or contacting pins as contacting elements passing through said at least one opening and connected to the actuator for electrical control of the actuator.

19. The actuating unit according to claim 18, wherein the actuator is tensioned by means of a spring element between the first cap and a second cap, with the actuator being arranged to expand and/or contract on excitation essentially in the direction of the two caps.

20. The actuating unit according to claim 18, wherein the spring element is embodied as a tubular spring and is arranged to surround the actuator.
